(19) United States
(12) Patent Application Publication
(10) Pub. No.: US 2025/0068351 A1
(43) Pub. Date: Feb. 27, 2025

(54) OPERATION METHOD OF MEMORY CONTROLLER, MEMORY CONTROLLER AND MEMORY SYSTEM

(71) Applicant: Yangtze Memory Technologies Co., Ltd., Wuhan, Hubei (CN)

(72) Inventors: Xiao Shao, Wuhan (CN); Qian Sun, Wuhan (CN)

(21) Appl. No.: 18/529,839

(22) Filed: Dec. 5, 2023

(30) Foreign Application Priority Data
Aug. 22, 2023 (CN) 202311063404.0

(51) Int. Cl. G06F 3/06

(52) U.S. Cl. CPC G06F 3/0655; G06F 3/0604; G06F 3/0679

(57) ABSTRACT

The present application provides an operation method of a memory controller, a memory controller and a memory system. The operation method includes: in response to a data write instruction, determining a first memory cell block into which data is to be written; determining whether a target parameter of the first memory cell block is greater than a first threshold; and in response to the target parameter of the first memory cell block being not greater than the first threshold, writing the data into the first memory cell block. In the present application, when the target parameter of an open block is not greater than a preset first threshold, that is, when unprogrammed memory cell pages are less affected, the erase page check is omitted and data is written into the first memory cell block.

### REFERENCE TO RELATED APPLICATIONS

This application claims the benefit of and priority to China Application No. 202311063404.0, filed on Aug. 22, 2023, which is hereby incorporated by reference in its entirety.

### TECHNICAL FIELD

The present application belongs to the field of semiconductor chip technologies, and relates to an operation method of a memory controller, a memory controller and a memory system.

### BACKGROUND

NAND memory, as a non-volatile memory, has the advantages of low cost, high capacity, and fast rewriting speed. In NAND memory, peripheral circuits supply power to memory cells to enable various logic operations, such as read operations, program operations, and erase operations.

### BRIEF DESCRIPTION OF THE DRAWINGS

In order to illustrate the technical solutions in the present application more clearly, the accompanying drawings required in some implementations of the present application will be briefly introduced in the following. Obviously, the accompanying drawings in the following description are only drawings of some implementations of the present application. For those of ordinary skill in the art, other drawings can also be obtained based on these drawings. In addition, the drawings in the following description can be regarded as schematic diagrams, and are not limitations on the actual size of the product, the actual process of the method, the actual timing of signals, and the like involved in the examples of the present disclosure.

FIG. 1 is a schematic structural diagram of a possible memory cell block according to an implementation of the present application;

FIG. 2 is a partial cross-sectional view of a possible memory cell string according to an implementation of the present application;

FIG. 3 is a schematic structural diagram of another possible memory cell block according to an implementation of the present application;

FIG. 4 is a schematic diagram of voltage application to word lines and select lines for performing read operations on memory cells;

FIG. 5 is a schematic diagram of read result determination in performing a read operation on memory cells;

FIG. 6 is a schematic diagram of a possible memory system according to an implementation of the present application;

FIG. 7 is a schematic structural diagram of a memory and peripheral circuits according to an implementation of the present application;

FIG. 8 is a schematic flowchart of an operation method of a memory controller in the memory system according to an implementation of the present application;

FIG. 9 is a schematic flowchart illustrating the memory responding to a first write command in the memory system according to an implementation of the present application;

FIG. 10 is a possible comparison diagram of programming results of the memory responding to the first write command according to the implementation of the present application;

FIG. 11 is another possible comparison diagram of programming results of the memory responding to the first write command according to an implementation of the present application;

FIG. 12 is a schematic flowchart illustrating the memory responding to a second write command in the memory system according to an implementation of the present application;

FIG. 13 is a possible comparison diagram of programming results of the memory responding to the second write command according to an implementation of the present application;

FIG. 14 is another comparison diagram of programming results of the memory responding to the second write command according to an implementation of the present application;

FIG. 15 is a schematic flowchart illustrating the memory responding to a third write command in the memory system according to an implementation of the present application;

FIG. 16 is a possible comparison diagram of programming results of the memory responding to the third write command according to an implementation of the present application;

FIG. 17 is a schematic flowchart illustrating the memory responding to a detection command in the memory system according to an implementation of the present application; and

FIG. 18 is a schematic structural diagram of a memory controller according to an implementation of the present application.

Reference numerals: 100, memory cell block; 110, memory cell slice; 111, memory cell string; 112, top select gate; 113, dummy memory cell; 114, memory cell; 115, bottom select gate; 216, memory cell page; 210, memory stack layer; 211, gate conductive layer; 212, dielectric layer; 220, substrate; 230, string select line; 240, word line; 250, ground select line; 300, memory system; 310, memory controller; 320, memory; 400, peripheral circuit; 410, I/O interface; 420, control logic unit; 430, row decoder; 340, voltage generator; 450, page buffer; 360, column decoder; 470, data bus; 480, register; 500, memory cell array; 600, processor; 700, buffer.

### DETAILED DESCRIPTION

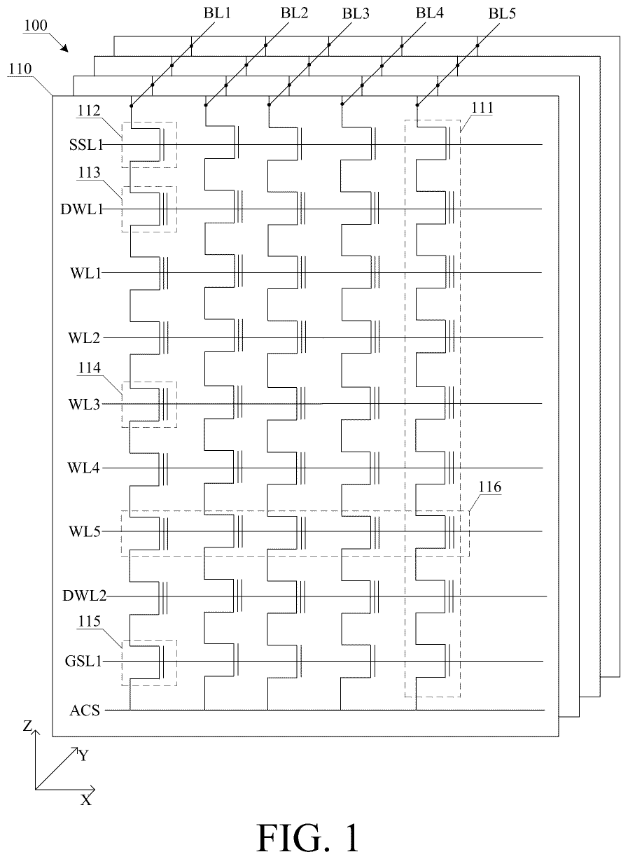

The technical solutions in some examples of the present disclosure will be clearly and completely described below in conjunction with FIGS. 1-18. Apparently, the described examples are merely some of the examples of the present disclosure, not all of them. All other examples obtained by those of ordinary skill in the art based on the examples provided in the present disclosure fall within the protection scope of the present disclosure.

Throughout the specification and claims, the term “comprising” is interpreted in an open and inclusive sense, i.e., “including, but not limited to” unless required otherwise in the context. In the description of the specification, the terms “one example”, “some examples”, “example”, “in some examples” are intended to indicate particular features, structures, materials or characteristics associated with the examples are included in at least one example of the present disclosure. Schematic representations of the above terms are not referring to the same example. Furthermore, the particular features, structures, materials or characteristics may be included in any suitable manner in any one or more examples.

As disclosed hereafter, the terms “first” and “second” are used for descriptive purposes only, and shall not be understood as indicating or implying relative importance or implicitly specifying the quantity of indicated technical features. Thus, a feature defined by “first” and “second” may explicitly or implicitly include one or more of these features. In the description of the examples of the present disclosure, “plurality” means two or more, unless otherwise specified.

When describing some examples, the expression “coupled” and its derivatives may be used. For example, when describing some examples, the term “coupled” may be used to indicate that two or more components are in direct physical or electrical contact, and in this case, “coupled” can also be described as “connected”. In addition, the term “coupled” may also mean that two or more components are not in direct contact with each other, but still cooperate or interact with each other. The examples disclosed as disclosed here are not limited by the context as disclosed here.

The use of “configured to” as disclosed here means open and inclusive language that does not exclude devices that are adapted to or configured to perform additional tasks or operations.

Flash is a non-volatile memory that can be electrically erased and reprogrammed, which may include memories with two architectures: NOR and NAND. The present application takes NAND flash as an example for further explanation. A three-dimensional (3D) NAND flash memory cell array may include multiple memory cell blocks. A memory cell block in which all memory cell pages have been programmed in the memory cell blocks is referred to as a close block, and a memory cell block in which only memory cell pages corresponding to a part of word lines have been programmed (the remaining memory cell pages are unprogrammed) in the memory cell blocks is referred to as an open block.

As shown in FIG. 1, the memory cell block 100 may include multiple memory cell strings 111, and N memory cell strings 111 are arranged along an X-axis to form a memory cell slice 110 (which may also be referred to as a memory cell group). M memory cell slices 110 are arranged along a Y-axis to form a memory cell block 100. As an example, N=5, and M=4. Each memory cell string 111 may include a top select gate (TSG) 112, a dummy (DMY) memory cell 113, a plurality of memory cells 114, and a bottom select gate (BSG) 115 stacked in series along a Z-axis. The X-axis, Y-axis and Z-axis are horizontal axis, longitudinal axis and vertical axis of the space rectangular coordinate system respectively.

In the implementation of the present application, the memory cell 114 in the NAND flash may be a device capable of storing data, such as a floating gate transistor or a charge trap type field effect transistor.

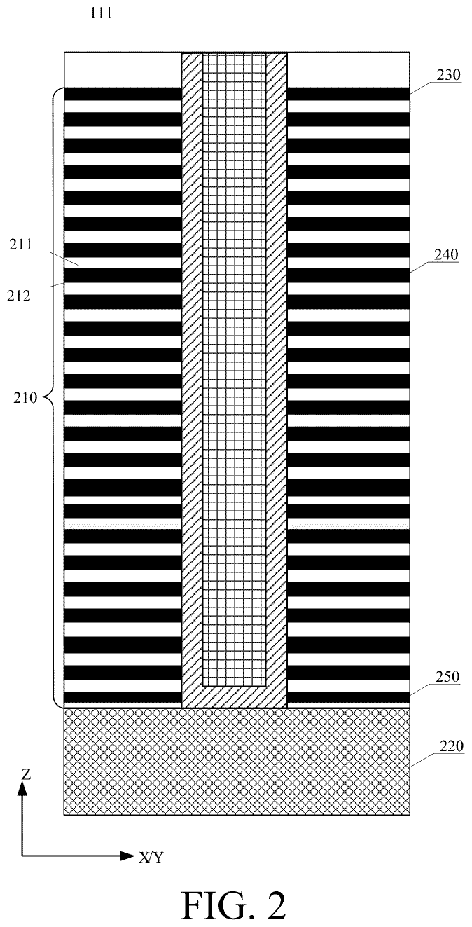

FIG. 2 shows a partial cross-sectional view of a possible memory cell string 111 according to the present application. The memory cell string 111 may extend vertically through a memory stack layer 210 over a substrate 220. Substrate 220 may include silicon (e.g., monocrystalline silicon), silicon germanium (SiGe), gallium arsenide (GaAs), germanium (Ge), silicon on insulator (SOI), germanium on insulator (GOI), or any other suitable materials.

The memory stack layer 210 may include alternating gate conductive layers 211 and dielectric layers 212. The number of memory cells 114 in the memory cell string 111 may be determined by the number of gate conductive layers 211 and dielectric layers 212 in the memory stack layer 210.

The gate conductive layer 211 may include conductive materials including, but not limited to, tungsten (W), cobalt (Co), copper (Cu), aluminum (Al), polysilicon, doped silicon, silicide, or any combination thereof. In some implementations, each gate conductive layer 211 includes a metal layer, such as a tungsten layer. In some implementations, each gate conductive layer 211 includes a doped polysilicon layer. Each gate conductive layer 211 may include a control gate surrounding the memory cell 114. The gate conductive layer 211 at the top of the memory stack layer 210 may extend laterally as a string select line (SSL) 230, the gate conductive layer 211 at the bottom of the memory stack layer 210 may extend laterally as a ground select line (GSL) 250, or the gate conductive layer 211 between the string select line 230 and the ground select line 250 may extend laterally as a word line (WL) 240.

It should be understood that, although not shown in FIG. 2, additional components of memory cell string 111 may be formed, including but not limited to gate line slits/source contacts, local contacts, interconnect layers, etc.

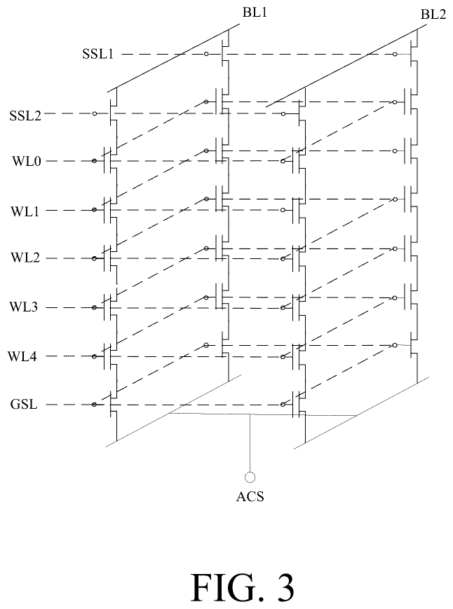

As shown in FIGS. 1 and 3, for M memory cell strings 111 in the same memory cell slice 110, the gates of the top select gates 112 in each memory cell string 111 are coupled to the same string select line, and the gates of the bottom select gates 115 in each memory cell string 111 are coupled to the same ground select line.

The M memory cell strings 111 in the memory cell slice 110 are coupled to M bit lines (BL) in one-to-one correspondence. For example, the drains of the top select gates 112 in the memory cell strings 111 are coupled to the bit lines. In order to reduce the number of bit lines, the memory cell strings 111 in N memory cell slices 110 can share M bit lines. That is, a memory cell string 111 in any one memory cell slice 110 and memory cell strings 111 at the corresponding position in the other (N−1) memory cell slices 110 are coupled to the same bit line.

For the N*M memory cell strings 111 in the N memory cell slices 110, a control gate of a memory cell 114 in any one memory cell string 111 and the control gates of memory cells 114 at the corresponding position in other (N*M−1) memory cell strings 111 are coupled to the same word line. Furthermore, the control gate of a dummy memory cell 113 in any one memory cell string 111 and the control gates of the dummy memory cell 113 at the corresponding position in other (N*M−1) memory cell strings 111 are coupled to the same dummy word line (DWL). The memory cells 114 coupled to the same word line in a memory cell slice 110 may be referred to as a memory cell page 216 (a physical page).

The sources of the bottom select gates 115 in the N*M memory cell strings 111 may be coupled to a common source line (CSL). The common source line may also be referred to as an array common source (ACS). It should be noted that the drawings of the present application only illustrate the structure of the memory 320 in some implementations. In practice, the memory 320 can be structured in other ways. For example, the sources of the bottom select gates 115 in the N*M memory cell strings 111 can be similar to the drains. The memory cell strings 111 in N memory cell slices 110 can share M source lines. That is, the memory cell string 111 in any one memory cell slice 110 and the memory cell strings 111 at the corresponding position in other (N—1) memory cell slices 110 are coupled to the same source line.

The memory cell page 216 is the smallest unit for reading/writing in the memory cell block 100. Performing a read operation on the memory cell page 216 is to measure the threshold voltages Vt of all memory cells in the memory cell page 216. Because it is not easy to realize direct measurement of the threshold voltage Vt of a memory cell, and output current of the memory cell is related to a gate voltage and the threshold voltage Vt, the threshold voltage Vt of the memory cell is determined by measuring the current.

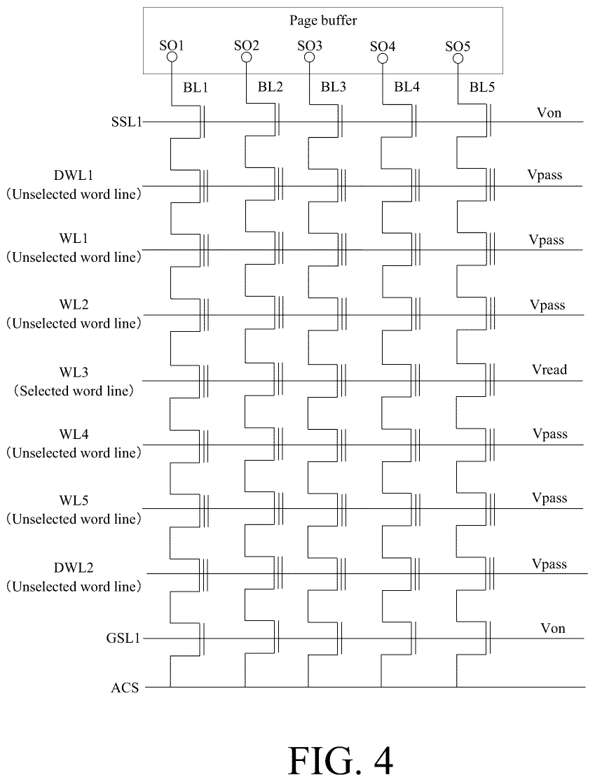

As shown in FIG. 4, when performing a read operation, a bit line (BL) coupled to the memory cell string where the memory cell to be read is located and a sensing node (SO) in the corresponding page buffer are first charged. Afterwards, a turn-on voltage Von is applied to select lines (such as SSL1, GSL1) of the memory cell string where the memory cell to be read is located, a read voltage Vread is applied to a selected WL coupled to the memory cell to be read, and a pass voltage Vpass is applied to unselected WLs other than the selected WL.

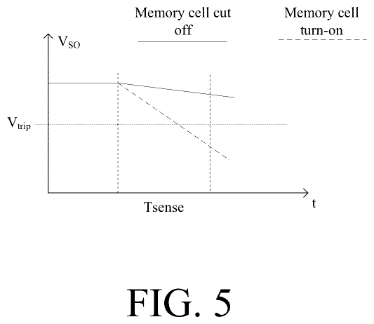

As shown in FIG. 5, after the sensing duration Tsense, the state of the memory cell is obtained by comparing the magnitudes of a voltage V_{SO} at the sensing node and a trip voltage Vtrip. In an example, if the voltage V_{SO} of the sensing node is greater than the trip voltage Vtrip, it means that the memory cell to be read is turned off (the discharge circuit of the sensing node is turned off, and the sensing node cannot be discharged), that is, the threshold voltage Vt is greater than the read voltage Vread. At this time, data “0” is read from the memory cell to be read. Similarly, if the voltage V_{SO} at the sensing node is less than the trip voltage Vtrip, it means that the memory cell to be read is turned on (the discharge circuit of the sensing node is turned on, and the sensing node is discharged), that is, the threshold voltage Vt is less than the read voltage Vread. At this time, data “1” is read from the memory cell to be read.

During the read operation, a strong electric field will be formed between the gate and channel of the memory cells coupled to the unselected word lines due to the pass voltage Vpass, and this electric field has a certain probability of causing charges to enter the floating gate (or charge well) of the memory cell, thereby causing read disturb (increasing the threshold voltage of the memory cell), and a weak programming effect on the memory cells coupled to the unselected word lines. The accumulated weak programming may cause the data bits of the memory cells to flip, and the accuracy of subsequent programming of unprogrammed memory cell pages is affected. Therefore, when programming an open block, it can be determined whether the open block meets programming conditions by an erase page check, and when the programming conditions are met, the unprogrammed memory cell pages in the open block are programmed (write data). However, it takes time to perform the erase page check on the open block, thus it takes a longer time to program the open block.

In the implementation of the present application, the degree of impact of disturb on the unprogrammed memory cell pages in the open block is determined based on the relationship between a target parameter of the open block and a preset first threshold. When the target parameter of the open block is not greater than the preset first threshold, the unprogrammed memory cell pages are less impacted, and the execution of the erase page check can be omitted and data can be written into the first memory cell block. It saves the time to perform the erase page check and reduces the time to program open blocks, thereby reducing the programming time of the memory.

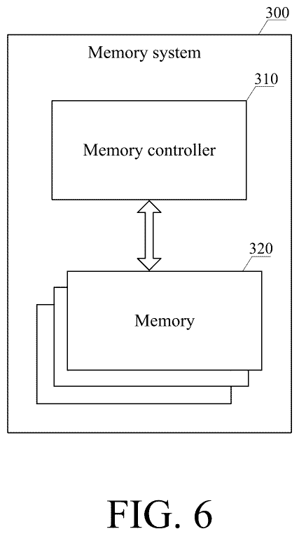

As shown in FIG. 6, an example of the present application provides a memory system 300, including a memory controller 310 and a memory 320. The memory controller 310 is configured to store data to the memory 320 or read data from the memory 320. The memory system 300 can be applied and packaged into different types of electronic devices, for example, mobile phones (for example, cell phones), desktop computers, tablet computers, notebook computers, servers, vehicle-mounted equipment, game consoles, printers, positioning devices, wearable devices, smart sensors, mobile power supply, virtual reality (VR) devices, augmented reality (AR) devices, servers and any electronic device that can store data.

Of course, the memory controller 310 may also perform any other suitable functions, such as formatting the memory 320. For example, the memory controller 310 may communicate with external devices (e.g., a host) via at least one of various interface protocols. Interface protocols can include at least one of universal serial bus (USB) protocol, multimedia card (MMC) protocol, peripheral component interconnect (PCI) protocol, PCI Express (PCI-E) protocol, advanced technology attachment (ATA) protocol, serial ATA protocol, parallel ATA protocol, small computer system interface (SCSI) protocol, enhanced small disk interface (ESDI) protocol, or integrated drive electronics (IDE) protocol.

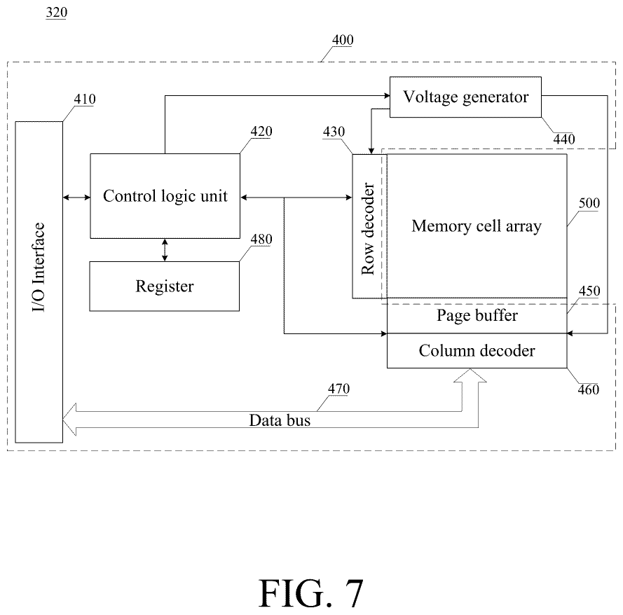

In some examples, as shown in FIG. 7, the above-mentioned memory 320 includes a memory cell array 500 and a peripheral circuit 400 coupled to the memory cell array 500. The peripheral circuit 400 is configured to control the memory cell array 500. The memory cell array 500 may include a plurality of memory cell blocks 100 as shown in FIG. 1.

As shown in FIG. 7, the peripheral circuit 400 may include an I/O interface 410, a control logic unit 420, a row decoder 430, a voltage generator 440, a page buffer 450, a column decoder 460, a data bus 470 and a register 480. It should be understood that in some examples, additional circuits not shown in FIG. 7 may also be included. Memory cell array 500 may be coupled to the peripheral circuit 400 via bit lines, common source lines, string select lines, word lines, ground select lines, etc. For example, bit lines are coupled to the page buffer 450 and word lines are coupled to the row decoder 430.

The I/O interface 410 may be coupled to the control logic unit 420 and act as a control buffer to buffer and relay control commands received from the memory controller 310 (e.g., memory controller 310 in FIG. 6) to the control logic unit 420, and buffer and relay status information received from the control logic unit 420 to the memory controller 310. I/O interface 410 may also be coupled to the page buffer 450 via the data bus 470 and act as a data I/O interface 410 and a data buffer to buffer and relay data to or from the memory cell array 500.

The control logic unit 420 may be coupled to the voltage generator 440, the page buffer 450, the column decoder 460, the row decoder 430, the I/O interface 410 and the like, and be configured to control operations of various peripheral circuits 400. The control logic unit 420 may generate operation signals in response to a command (CMD) or a control signal from the memory controller 310 to control operations of the row decoder 430, the column decoder 460, the page buffer 450, and the voltage generator 440. The command may be a program command, a read command, etc.

The voltage generator 440 may use an external power supply voltage or an internal power supply voltage to generate various voltages for performing operations such as erase, program, read, and verify on the memory cell array 500, such as a program voltage Vpgm, a pass voltage Vpass, a read voltage Vread, a verification voltage Vvfy and the like applied to the word lines, and a program inhibit voltage Vinhibit, a program select voltage Vss and the like applied to the bit lines, and combinations thereof.

The row decoder 430 may supply the word line voltage generated from the voltage generator 440 to the selected word lines and unselected word lines of the memory cell array 500 in response to operation signals from the control logic unit 420. As described in detail below, the row decoder 430 is configured to perform program operations on cells of the memory 320 coupled to one or more selected word lines in the memory cell array 500.

Column decoder 460 may select one or more memory cell strings 111 in memory cell array 500 in response to operation signals from the control logic unit 420.

The page buffer 450 may read data from and program (write) data to the memory cell array 500 according to a control signal from the control logic unit 420. In one example, the page buffer 450 may store program data (write data) to be programmed into the memory cell array 500. In another example, page buffer 450 may perform a program verification operation to ensure that data has been correctly programmed into memory cells 114 coupled to the selected word lines. In yet another example, the page buffer 450 may also detect low power signals from bit lines representing data bits stored in memory cells 114 and amplify small voltage swings to recognizable logic levels during read operations.

The register 480 may be coupled to the control logic unit 420 and include status registers, command registers and address registers for storing status information, command operation codes (OP codes) and command addresses for controlling the operations of each peripheral circuit 400.

Those skilled in the art should understand that the operations performed by the row decoder 430, the page buffer 450, the control logic unit 420, and the voltage generator 440 described in this application may be performed by a processing circuit. The processing circuit may include, but is not limited to, hardware of a logic circuit or a hardware/software combination of a processor executing software.

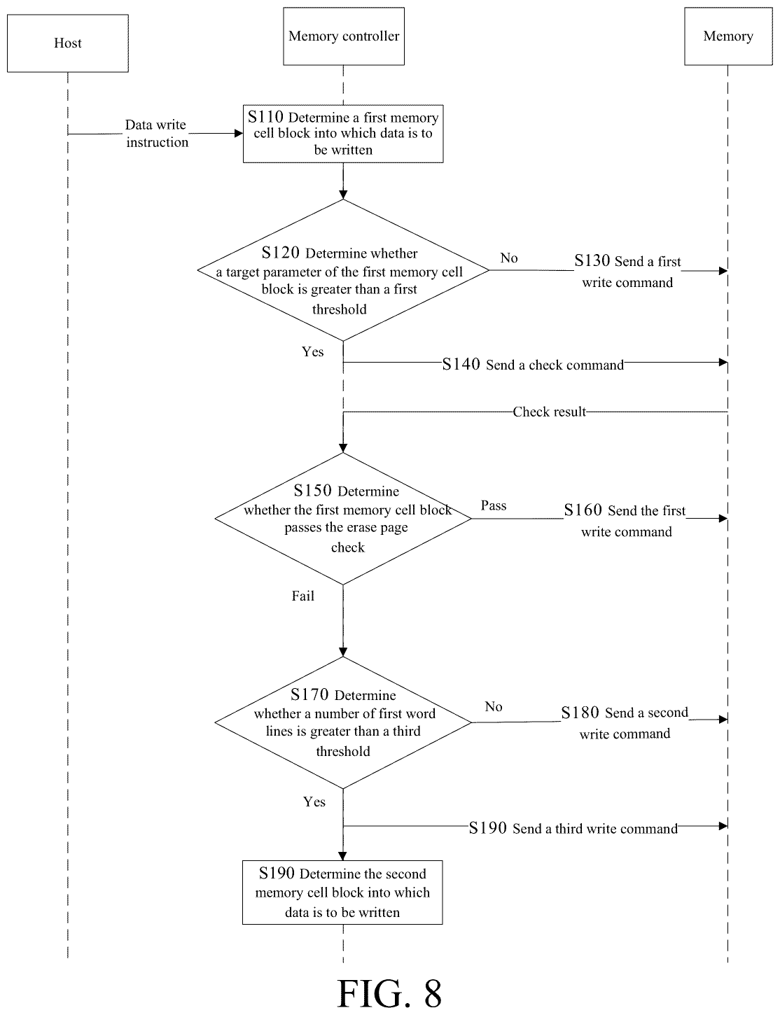

In some examples, as one implementation of the memory system of the present application, as shown in FIG. 8, operations S110-S190 are performed as follows.

S110. In response to a data write instruction sent by a host, determining, by a memory controller, a first memory cell block into which data is to be written, that is, allocating a physical address for the data to be written.

In some examples, when the memory controller 310 performs a program operation on the memory 320, open blocks will inevitably appear, and the open blocks include programmed memory cell pages and unprogrammed memory cell pages. There is almost no charge stored in the floating gates (or charge wells) of all memory cells 114 in the unprogrammed memory cell pages, and thus the threshold voltage is low. Therefore, during a read operation, when a pass voltage Vpass is applied to the unselected word lines, charges are more likely to enter the floating gate (or charge trap) of the memory cells 114 in the unprogrammed memory cell pages. In addition, the charge migration that occurs in the floating gate (or charge well) is an important physical mechanism that affects the stability of the data stored in the memory 320. The greater the difference between threshold voltages of two adjacent memory cells 114 in the memory cell string 111 is, the more serious the charge migration will be. Therefore, for open blocks, the adjacent programmed memory cell pages (high threshold voltage) and unprogrammed memory cell pages (low threshold voltage) in the same memory cell slice 110 will have relatively serious charge migration, leading to poor data retention of the programmed memory cell pages adjacent to the unprogrammed memory cell pages. In other words, compared to close blocks, open blocks have worse data retention and are more susceptible to read disturb. Therefore, when determining the first memory cell block into which data is to be written, the memory controller 310 will prioritize the open block as the first memory cell block.

S120. Determining, by the memory controller, whether a target parameter of the first memory cell block is greater than a first threshold.

The target parameter of the first memory cell block may include a read count of the first memory cell block. Memory controller 310 may send a read command to the memory 320 to read data from a programmed memory cell page in the memory 320. Each time data is read from a programmed memory cell page, read disturb will occur on the unprogrammed memory cell pages. When the read count is greater than a preset number, the accumulated read disturb may cause data bit flips in unprogrammed memory cell pages (for example, data “1” becomes data “0”), affecting the accuracy of subsequent programming of unprogrammed memory cell pages.

The target parameter of the first memory cell block may further include a placement duration of the first memory cell block, and the placement duration of the first memory cell block is a time difference between a current moment and a moment at which an erase operation was last performed on the first memory cell block. For the unprogrammed memory cell pages, charges (such as holes) migrate out of the floating gates (or charge wells) of the memory cells in the unprogrammed memory cell pages, which can increase the threshold voltage of the memory cells in the unprogrammed memory cell pages. When the placement duration is longer than a preset duration, the accumulated migrated charge amount may cause data bit flips in the unprogrammed memory cell pages, affecting the accuracy of subsequent programming of unprogrammed memory cell pages.

It should be understood that the present application can use either the read count or the placement duration (or a combination of both) as the target parameter of the first memory cell block. That is, when the read count is greater than the preset number or the placement duration is greater than a preset duration, it can be considered that the target parameter of the first memory cell block is greater than the first threshold.

In addition, as the erase count of the memory cell block 100 increases, a tunneling layer between the floating gate (or charge well) and the channel is increasingly worn, and control of charges in the floating gate (or charge well) will also become increasingly difficult (that is, read disturb and charge migration are more likely to affect memory cells). For the unprogrammed memory cell pages, the more the erase count, the easier it is for data bit flips to occur.

Therefore, in the present application, the memory controller 310 further determines the first threshold based on the erase count of the first memory cell block.

In some examples, the memory controller 310 may be configured with a correspondence between the erase count and the first threshold (such as a mapping table, a lookup table or a mapping function, and the like). The greater the erase count, the smaller the first threshold. For example, when the erase count of the first memory cell block is greater than a second threshold, the memory controller 310 determines that the first threshold is a threshold a. When the erase count of the first memory cell block is not greater than the second threshold, the memory controller 310 determines that the first threshold is a threshold b, wherein the threshold a is less than the threshold b.

S130. In response to the target parameter of the first memory cell block being not greater than the first threshold, sending, by the memory controller, a first write command to the memory.

The first write command instructs the peripheral circuit 400 in the memory 320 to write data into the first memory cell block. That is, when the target parameter of the first memory cell block is not greater than a preset number (or the placement duration of the first memory cell block is not greater than a preset duration), it indicates that the read disturb (or charge migration) has a less impact on the unprogrammed memory cell pages, and unprogrammed memory cell pages can still meet the programming conditions. The accuracy of written data can be ensured for the peripheral circuit 400 in the memory 320 writing data into any unprogrammed memory cell page in the first memory cell block.

When writing data into a memory cell block, there may be multiple programming modes, such as by-WL programming and by-string programming. The so-called by-WL programming means that after the memory cell page coupled to the current word line is programmed, the memory cell page coupled to the next word line is then programmed. The so-called by-string programming means that after the memory cell page in the current memory cell slice 110 is programmed, the memory cell page in the next memory cell slice 110 is then programmed.

As an example, a memory cell block includes two memory cell slices 110 (group 0 and group 1) and three word lines (WL0, WL1, and WL2). This example includes six memory cell pages. Each memory cell page and its corresponding number are as shown in the following table:

| Memory cell page | Corresponding number |
|---|---|
| Memory cell page in group 0 coupled to WL0 | WL0 group 0 |
| Memory cell page in group 1 coupled to WL0 | WL0 group 1 |
| Memory cell page in group 0 coupled to WL1 | WL1 group 0 |
| Memory cell page in group 1 coupled to WL1 | WL1 group 1 |
| Memory cell page in group 0 coupled to WL2 | WL2 group 0 |
| Memory cell page in group 1 coupled to WL2 | WL2 group 1 |

The programming sequence of by-WL programming is: WL0 group 0, WL0 group 1, WL1 group 0, WL1 group 1, WL2 group 0, and WL2 group 1. That is, when programming by WL, if WL0 group 0 is a programmed memory cell page, the second write command instructs the peripheral circuit 400 in the memory 320 to write data into the unprogrammed memory cell page starting from WL0 group 1. If WL0 group 0 and WL0 group 1 are programmed memory cell pages, the second write command instructs the peripheral circuit 400 in the memory 320 to write data into the unprogrammed memory cell page starting from WL1 group 0.

The programming sequence of by-string programming is: WL0 group 0, WL1 group 0, WL2 group 0, WL0 group 1, WL1 group 1, and WL2 group 1. That is, when programming by string, if WL0 group 0 is a programmed memory cell page, the second write command instructs the peripheral circuit 400 in the memory 320 to write data into the unprogrammed memory cell page starting from WL1 group 0. If WL0 group 0 and WL1 group 0 are programmed memory cell pages, the second write command instructs the peripheral circuit 400 in the memory 320 to write data into the unprogrammed memory cell page starting from WL2 group 0.

The present application does not limit the programming mode of programming memory cell blocks.

S140. In response to the target parameter of the first memory cell block being greater than the first threshold, sending, by the memory controller, a detection command to the memory.

The detection command instructs the peripheral circuit 400 in the memory 320 to perform an erase page check on the first memory cell block. That is, the peripheral circuit 400 is instructed to read the data of the unprogrammed memory cell page in the first memory cell block, and the peripheral circuit 400 sends the read data (i.e., a detection result) to the memory controller 310. Under normal circumstances (the unprogrammed memory cell page meets the programming conditions), all memory cells in the unprogrammed memory cell page should be in an erased state, and the data read by the peripheral circuit 400 are all data “1”. Under exception circumstances (the unprogrammed memory cell page does not meet the programming conditions), there are memory cells that are in a programmed state in the unprogrammed memory cell page, and the data read by the peripheral circuit 400 are all data “0”.

S150. Receiving the detection result sent by the memory and determining whether the first memory cell block passes the erase page check.

In some examples, the memory controller 310 can perform a decoding verification on data read from the detection result sent by the peripheral circuit 400 (for example, by low density parity-check code (LDPC)), and determine whether the first memory cell block passes the erase page check according to the decoding verification result.

To reduce the time for the erase page check, the peripheral circuit 400 reads an unprogrammed memory cell page adjacent to the programmed memory cell page. That is, when programming by WL, if WL0 group 0 is a programmed memory cell page, the peripheral circuit 400 reads the data of WL0 group 1. If WL0 group 0 and WL0 group 1 are programmed memory cell pages, the peripheral circuit 400 reads the data of WL1 group 0.

Further, in other implementations, the memory controller 310 may further determine a read voltage according to the erase count of the first memory cell block, the read count of the first memory cell block, and the placement duration of the first memory cell block. The read voltage is to applied to the selected word line when performing the erase page check on the first memory cell block to read data of the unprogrammed memory cell page in the selected word line. In some examples, the memory controller 310 is also configured with a lookup table for querying the read voltage. The placement duration of the first memory cell block is used as the input to the lookup table to query the read voltage. Alternatively, the read count of the first memory cell block can be used as the input to the lookup table to query the read voltage. Still alternatively, the erase count of the first memory cell block, the read count of the first memory cell block and the placement duration of the first memory cell block are combined as the input to the lookup table to query the read voltage.

S160. In response to the first memory cell block passing the erase page check, sending, by the memory controller, the first write command to the memory.

That is, the erase page check can indicate that the unprogrammed memory cell page is in an erased state. Thus, the accuracy of written data can be ensured for the peripheral circuit 400 in the memory 320 writing data into any unprogrammed memory cell page in the first memory cell block.

S170. In response to the first memory cell block failing the erase page check, determine whether a number of first word lines coupled to programmed memory cell pages in the first memory cell block is greater than a third threshold.

Since that the read disturb in reading data mainly affects the memory cells in the unselected word lines (to which a pass voltage Vpass is applied) adjacent to the selected word line (to which a read voltage Vread is applied). That is, when the unprogrammed memory cell page coupled to a third word line that is adjacent to the first word line does not meet the programming conditions because of data bit flips due to multiple read disturbs, the unprogrammed memory cell page coupled to a second word line that is not adjacent to the first word line can still meet the programming conditions.

S180. In response to the number of the first word lines being not greater than the third threshold, sending, by the memory controller, a second write command to the memory.

The second write command instructs the peripheral circuit 400 in the memory 320 to: write data into the unprogrammed memory cell page coupled to the second word line that is not adjacent to the first word line; and, to write invalid data into an unprogrammed memory cell page located between the programmed memory cell pages and the unprogrammed memory cell page coupled to the second word line. Thus, the memory space utilization of the first memory cell block (open block) may be increased to a certain extent, the threshold voltage difference between adjacent memory cell pages can be reduced, charge migration is reduced, and the data retention of the first memory cell block is improved.

S190. If the number of the first word lines being greater than the third threshold, determine, by the memory controller, a second memory cell block into which the data is to be written, and send a third write command to the memory.

The second memory cell block may be a completely unprogrammed memory cell block or an open block. When the second memory cell block is an open block, return to operation S110. When the second memory cell block is a completely unprogrammed memory cell block, the memory controller 310 may control the peripheral circuit 400 in the memory 320 to write data into the second memory cell block.

In addition, the third write command instructs the peripheral circuit 400 in the memory 320 to write invalid data into the unprogrammed memory cell page in the first memory cell block. As a result, the first memory cell block becomes a close block, and the threshold voltage difference between two adjacent memory cell pages is reduced, thereby reducing charge migration and improving data retention of the first memory cell block.

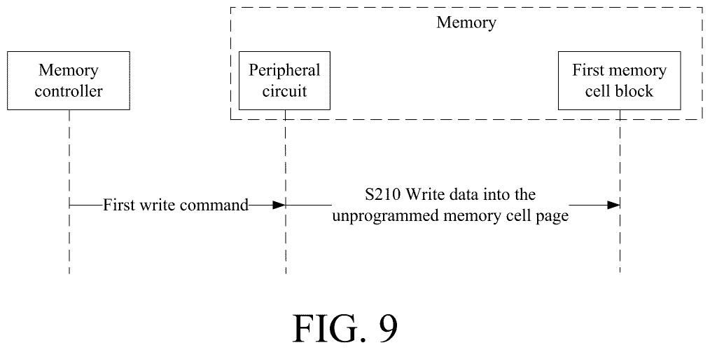

As shown in FIG. 9, the memory system according to the implementation of the present application further includes execution of operation S210.

S210. In response to the first write command sent by the memory controller, the peripheral circuit in the memory writes data into the unprogrammed memory cell page in the first memory cell block.

In some examples, the first write command is to instruct to write data into an unprogrammed memory cell that is also adjacent to a programmed memory cell. That is, in response to the first write command sent by the memory controller, the peripheral circuit in the memory may write data starting from an unprogrammed memory cell page in the first memory cell block that is also adjacent to the programmed memory cell.

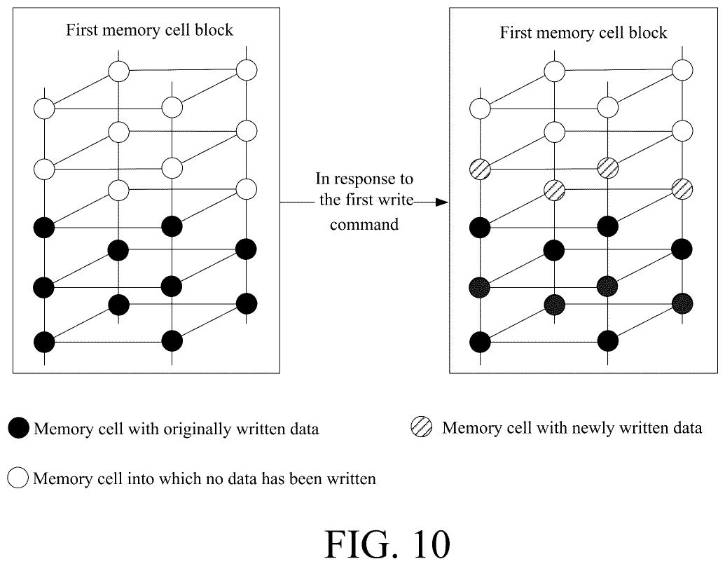

For example, as shown in FIG. 10, the memory cell pages coupled to the first and second of the word lines from bottom to top in the first memory cell block to be programmed are all programmed memory cell pages, the memory cell page coupled to the third of the word lines includes programmed memory cell pages and unprogrammed memory cell pages, and the memory cell pages coupled to the fourth and fifth of the word lines are all unprogrammed memory cell pages. At this time, in response to the first write command, the peripheral circuit 400 in the memory 320 writes data into the unprogrammed memory cell pages coupled to the third of the word lines, and writes data into the unprogrammed memory cell pages coupled to the fourth of the word lines.

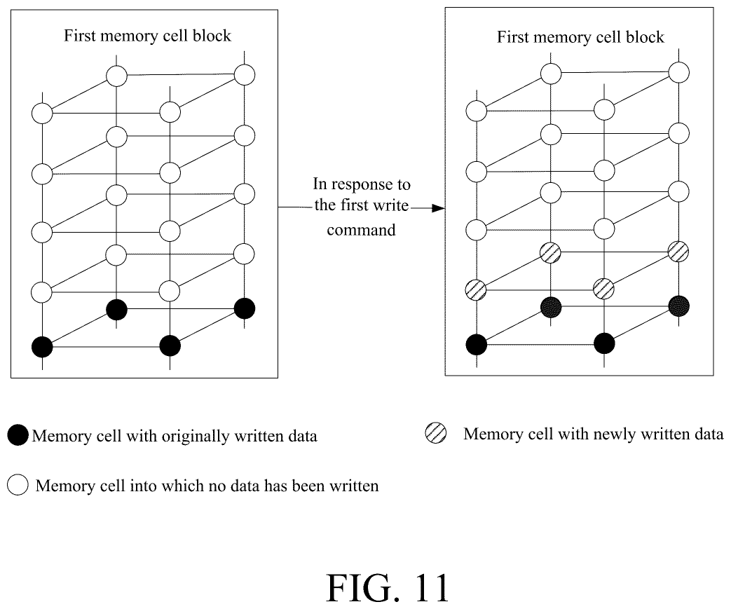

As shown in FIG. 11, the memory cell pages coupled to the first of the word lines from bottom to top in the first memory cell block to be programmed are all programmed memory cell pages. The memory cell pages coupled to the second, third, fourth and fifth of the word lines are all unprogrammed memory cell pages. At this time, in response to the first write command, the peripheral circuit 400 in memory 320 writes data into the unprogrammed memory cell pages coupled to the second of the word lines.

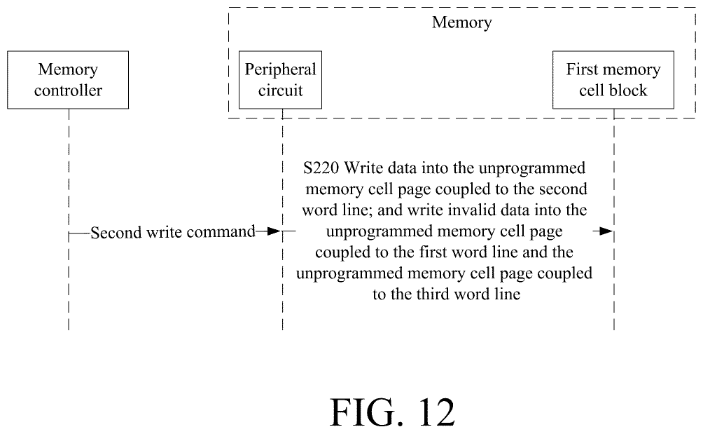

As shown in FIG. 12, the memory system according to the implementation of the present application further includes execution of operation S220.

S220. In response to the second write command sent by the memory controller, writing, by the peripheral circuit in the memory, data into the unprogrammed memory cell page coupled to the second word line in the first memory cell block; and, writing, by the peripheral circuit in the memory, invalid data into the unprogrammed memory cell page located between the programmed memory cell page and the unprogrammed memory cell page coupled to the second word line.

In some examples, the second word line is not adjacent to the first word line. That is, at least one third word line is located between the first word line and the second word line, and the number of third word lines located between the second word line and the first word line can be configured in advance. For example, one third word line may be located between the second word line and the first word line, or two third word lines may be located between the second word line and the first word line. There is at least one programmed memory cell page among the plurality of memory cell pages coupled to the first word line. The plurality of memory cell pages coupled to the second word line are all unprogrammed memory cell pages. The plurality of memory cell pages coupled to the third word line are all unprogrammed memory cell pages.

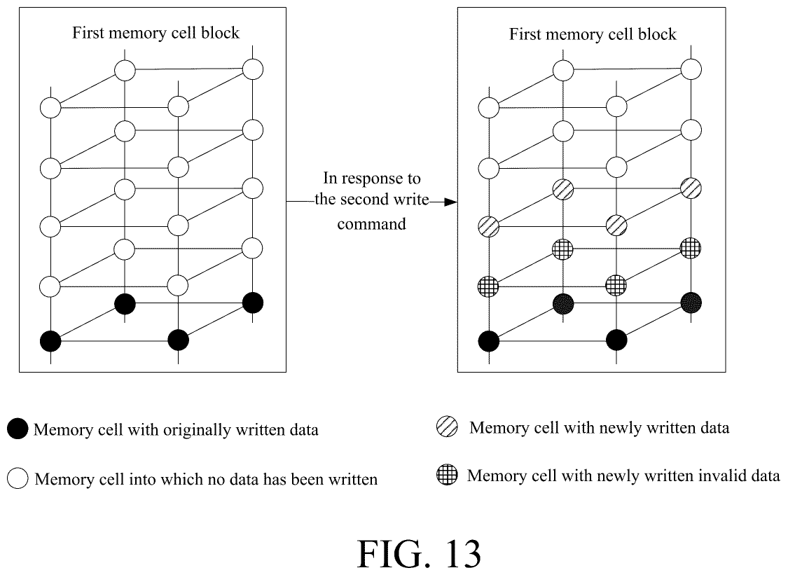

That is, among the plurality of memory cell pages coupled to the first word line, all memory cell pages are programmed memory cell pages. As shown in FIG. 13, the first of the word lines from bottom to top in the first memory cell block to be programmed is the first word line, the second of the word lines is the third word line, the third, fourth and fifth of the word lines are the second word lines. All memory cell pages coupled to the first word line are programmed memory cell pages. At this time, in response to the second write command, the peripheral circuit 400 in the memory 320 writes invalid data into the memory cell page coupled to the third word line into which no data has been written, and writes data into the memory cell page coupled to the second word line into which no data has been written.

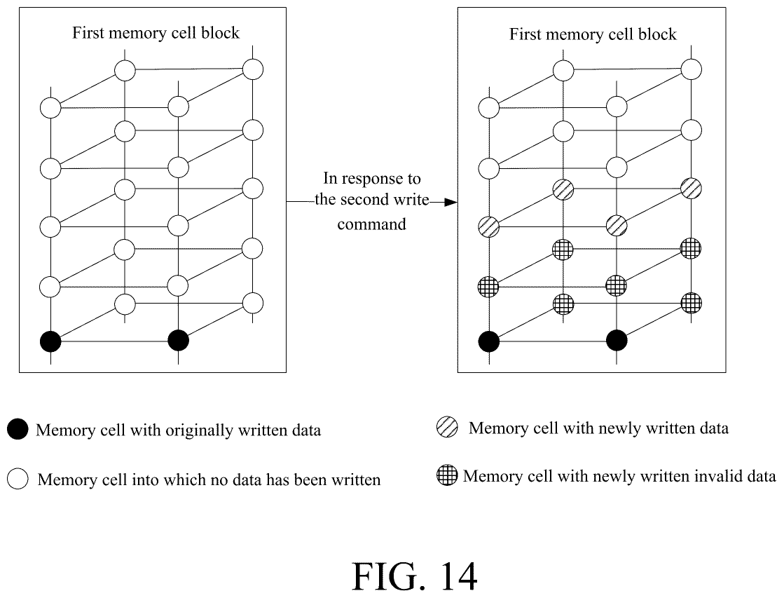

As shown in FIG. 14, among the plurality of memory cell pages coupled to the first word line, some of the memory cell pages may also be programmed memory cell pages. What differs from FIG. 13 is that the memory cell pages coupled to the first word line includes programmed memory cell pages and unprogrammed memory cell pages. At this time, in response to the second write command, the peripheral circuit 400 in the memory 320 writes invalid data into the memory cell page coupled to the first word line into which no data has been written and the memory cell page coupled to the third word line into which no data has been written, and writes data into the memory cell page coupled to the second word line into which no data is written.

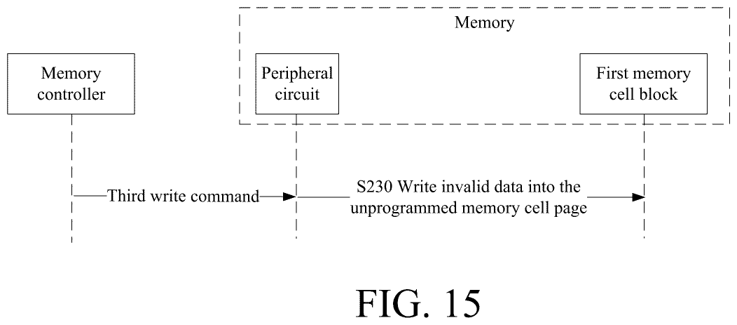

As shown in FIG. 15, the memory system according to the implementation of the present application further includes execution of operation S230.

S230. In response to the third write command sent by the memory controller, writing, by the peripheral circuit in the memory, invalid data into the unprogrammed memory cell page in the first memory cell block.

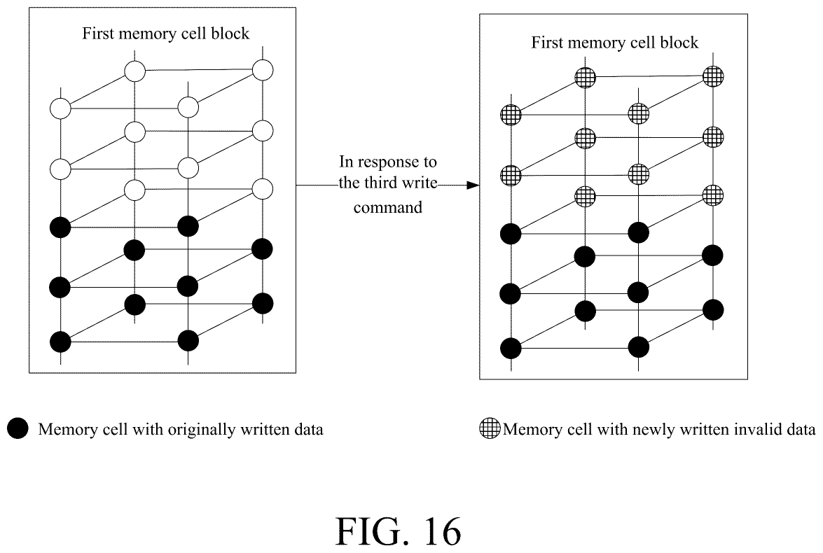

As shown in FIG. 16, the first memory cell block becomes a close block, so that the threshold voltage difference between two adjacent memory cell pages is reduced, thereby reducing charge migration and improving the data retention of the first memory cell block.

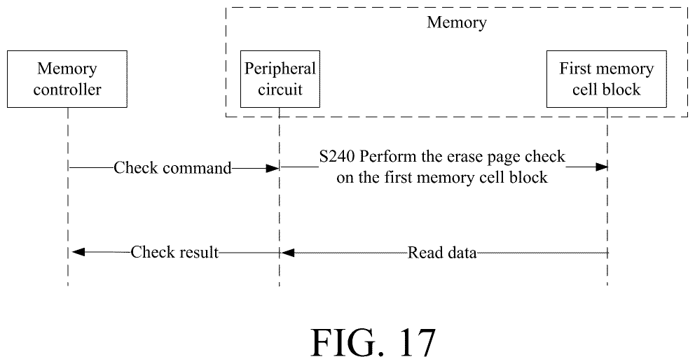

As shown in FIG. 17, the memory system according to the implementation of the present application also includes execution of operation S240.

S240. In response to the detection command, performing the erase page check on the first memory cell block and sending the detection result to the memory controller.

It should be understood that writing data into an unprogrammed memory cell page coupled to the first word line (or second word line) described in the present application is intended to indicate the starting memory cell page for writing data, and does not mean data is only written into the unprogrammed memory cell page of the first word line (or second word line). When data to be written requires multiple memory cell pages, the memory 320 can write data into other unprogrammed memory cell pages according to various programming modes (such as by-WL programming or by-string programming). For example, after data is written into all unprogrammed memory cell pages coupled to the first word line, data can be continued to be written into the unprogrammed memory cell pages coupled to the third word line and the second word line (or, after data is written into all unprogrammed memory cell pages in the current memory cell slice 110, data can also be written into all unprogrammed memory cell pages in the next memory cell slice 110), or even data can be continued to be written into next memory cell block (for example, a second memory cell block).

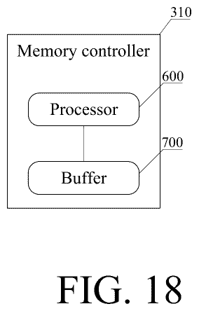

As shown in FIG. 18, this implementation of the present application provides a memory controller. The memory controller 310 includes a processor 600 and a buffer 700. The buffer 700 may be configured to buffer the erase count, the read count and the placement time of the first memory cell block and the number of the first word lines, etc. The processor 600 can perform the above operations S110 to S190.

Implementations of the present application further provide a computer-readable storage medium that stores computer-executable instructions, which, when executed, can implement the operations in the above method implementation, for example, performing the method as shown in FIG. 8.

Implementations of the present application provide a computer device, including a processor, and a readable storage medium coupled to the processor. The readable storage medium stores executable instructions, which, when executed by the processor, can implement the operations in the above method implementation, for example, performing the method as shown in FIG. 8.

Implementations disclosed in the present application provide an operation method of a memory controller, a memory controller, and a memory system for reducing programming time of the memory.

To achieve the above objects, the implementations of the present application adopt the following technical solutions.

In a first aspect, it is provided an operation method of a memory controller, comprising: in response to a data write instruction, determining a first memory cell block into which data is to be written; determining whether a target parameter of the first memory cell block is greater than a first threshold; and in response to the target parameter of the first memory cell block being not greater than the first threshold, writing the data into the first memory cell block.

In the present application, the target parameter of an open block reflects the impact on unprogrammed memory cell pages. When the target parameter of the open block is not greater than a preset first threshold, the unprogrammed memory cell pages are less impacted, thus an erase page check is omitted and the data is written into the first memory cell block. In this way, the time to perform the erase page check is saved, and the time to program the open block is reduced, thereby reducing the programming time of the memory.

In some implementations, the operation method further comprises: in response to the target parameter of the first memory cell block being greater than the first threshold, performing an erase page check on the first memory cell block; and in response to the first memory cell block passing the erase page check, writing the data into the first memory cell block. The erase page check can indicate that the unprogrammed memory cell pages are in an erased state, that is, no data bit flip occurs due to various effects. Therefore, when the peripheral circuit in the memory writes data into any unprogrammed memory cell page in the first memory cell block, the accuracy of the written data can be guaranteed.

In some implementations, the target parameter of the first memory cell block comprises a read count of the first memory cell block. Each time data is read from a programmed memory cell page, read disturb will occur on the unprogrammed memory cell pages, resulting in weak programming. When the read count is greater than a preset number, the accumulated read disturb may cause data bit flips occur on unprogrammed memory cell pages, affecting the accuracy of subsequent programming of the unprogrammed memory cell pages. Alternatively, the target parameter of the first memory cell block comprises a placement duration of the first memory cell block, and the placement duration of the first memory cell block is a time difference between a current moment and a moment at which an erase operation was last performed on the first memory cell block. When the placement duration is longer than a preset time duration, the amount of charge accumulated migration may also affect the accuracy of subsequent programming of unprogrammed memory cell pages. Therefore, in the present application, the read count of the first memory cell block or the placement duration of the first memory cell block can reflect whether the unprogrammed memory cell pages can meet programming conditions to a certain extent.

In some implementations, the operation method further comprises: determining the first threshold based on an erase count of the first memory cell block. As the erase count of a memory cell block increases, a tunneling layer between a floating gate (or a charge well) and a channel is increasingly worn, and read disturb and charge migration are more likely to affect the memory cell. That is, the first memory cell blocks with different numbers of erases are affected differently when having the same read count (or placement duration). Therefore, in the present application, the first threshold is determined based on the erase count of the first memory cell block, which can make the determination of the impact on the first memory cell block based on the read count (or placement duration) more accurate.

In some implementations, for unprogrammed memory cell pages, the larger the erase count, the easier it is for data bit flips to occur. Therefore, the determining the first threshold based on an erase count of the first memory cell block comprises: determining whether the erase count of the first memory cell block is greater than a second threshold; in response to the erase count of the first memory cell block being greater than the second threshold, determining the first threshold to be a threshold a; and in response to the erase count of the first memory cell block being not greater than the second threshold, determining the first threshold to be a threshold b, wherein the threshold a is smaller than the threshold b.

In some implementations, the operation method further comprises: in response to the first memory cell block failing the erase page check, determining whether a number of first word lines coupled to programmed memory cell pages in the first memory cell block is greater than a third threshold; in response to the number of the first word lines being not greater than the third threshold, writing data into an unprogrammed memory cell page coupled to a second word line in the first memory cell block, the second word line being not adjacent to the first word lines; and in response to the number of the first word lines being greater than the third threshold, determining a second memory cell block into which the data is to be written. Since the read disturb mainly affects the memory cells adjacent to the memory cell being read, the impact on the memory cell page in the second word line is smaller. Therefore, when the first memory cell block fails the erase page check, if the number of the first word lines is not greater than the third threshold, the memory space of the first memory cell block (open block) is better utilized while guaranteeing programming accuracy by writing data into the memory cell page in the second word line, and the memory space utilization of the first memory cell block is improved. If the number of the first word lines is greater than the third threshold, more data has been written into the first memory cell block and the memory space is limited. Therefore, the second memory cell block is determined to write data into the second memory cell block.

In some implementations, the operation method further comprises: in response to the number of the first word lines being not greater than the third threshold, writing invalid data into an unprogrammed memory cell page located between the programmed memory cell pages and the unprogrammed memory cell page coupled to the second word line. Therefore, the threshold voltage difference between adjacent memory cell pages is reduced, thereby reducing charge migration and improving data retention of the first memory cell block.

In some implementations, the operation method further comprises: in response to the number of the first word lines being greater than the third threshold, writing invalid data into the unprogrammed memory cell page in the first memory cell block. As a result, the first memory cell block becomes a close memory cell block, and the threshold voltage difference between two adjacent memory cell pages coupled to different word lines is reduced, thereby reducing charge migration and improving data retention of the first memory cell block.

In some implementations, the operation method also includes, before the performing an erase page check on the first memory cell block: determining a read voltage according to the erase count of the first memory cell block, the read count of the first memory cell block, and the placement duration of the first memory cell block. A small increase in the threshold voltage of memory cells in unprogrammed memory cell pages is acceptable (that is, it is not considered to affect the accuracy of programming). Therefore, according to the erase count, the read count and the placement duration, adjusting the read voltage can maximize the utilization of the memory space of the first memory cell block and improve the space utilization of the first memory cell block while ensuring the programming accuracy.

In a second aspect, it is provided a memory controller, comprising: a processor and a buffer. The buffer is configured to store a target parameter of a first memory cell block. The processor is configured to: in response to a data write instruction, determine the first memory cell block into which data is to be written; determine whether the target parameter of the first memory cell block is greater than a first threshold; and in response to the target parameter of the first memory cell block being not greater than the first threshold, write the data into the first memory cell block.

In some implementations, the processor is further configured to: in response to the target parameter of the first memory cell block being greater than the first threshold, perform an erase page check on the first memory cell block; and in response to the first memory cell block passing the erase page check, write the data into the first memory cell block.

In some implementations, the target parameter of the first memory cell block comprises a read count of the first memory cell block; or the target parameter of the first memory cell block comprises a placement duration of the first memory cell block, and the placement duration of the first memory cell block is a time difference between a current moment and a moment at which an erase operation was last performed on the first memory cell block, and the buffer is configured to perform at least one of: store the read count of the first memory cell block; or store the placement duration of the first memory cell block.

In some implementations, the processor is further configured to: determine the first threshold based on an erase count of the first memory cell block.

In some implementations, the processor determines the first threshold based on an erase count of the first memory cell block, and is configured to: determine whether the erase count of the first memory cell block is greater than a second threshold; in response to the erase count of the first memory cell block being greater than the second threshold, determine the first threshold to be a threshold a; and in response to the erase count of the first memory cell block being not greater than the second threshold, determine the first threshold to be a threshold b, wherein the threshold a is smaller than the threshold b.

In some implementations, the processor is further configured to: in response to the first memory cell block failing the erase page check, determine whether a number of first word lines coupled to programmed memory cell pages in the first memory cell block is greater than a third threshold; in response to the number of the first word lines being not greater than the third threshold, write data into an unprogrammed memory cell page coupled to a second word line in the first memory cell block, the second word line being not adjacent to the first word lines; and in response to the number of the first word lines being greater than the third threshold, determine a second memory cell block into which the data is to be written.

In some implementations, the processor is further configured to: in response to the number of the first word lines being not greater than the third threshold, write invalid data into an unprogrammed memory cell page located between the programmed memory cell pages and the unprogrammed memory cell page coupled to the second word line.

In some implementations, the processor is further configured to: in response to the number of the first word lines being greater than the third threshold, write invalid data into the unprogrammed memory cell page in the first memory cell block.

In some implementations, the processor is further configured to, before the performing an erase page check on the first memory cell block:

determine a read voltage according to the erase count of the first memory cell block, the read count of the first memory cell block, and the placement duration of the first memory cell block.

In a third aspect, a memory system is provided, comprising a memory and a memory controller coupled to the memory; wherein the memory controller is configured to: in response to a data write instruction, determine a first memory cell block into which data is to be written; determine whether a target parameter of the first memory cell block is greater than a first threshold; and in response to the target parameter of the first memory cell block being not greater than the first threshold, send a first write command to the memory, the first write command instructing the memory to write the data into the first memory cell block; and the memory is configured to: in response to the first write command, write the data into the first memory cell block.

In some implementations, the memory controller is further configured to: in response to the target parameter of the first memory cell block being greater than the first threshold, send a detection command to the memory, the detection command instructing the memory to perform an erase page check on the first memory cell block; receive a detection result sent by the memory and determine whether the first memory cell block passes the erase page check; and in response to the first memory cell block passing the erase page check, send the first write command to the memory; and the memory is further configured to: in response to the detection command, perform the erase page check on the first memory cell block, and send the detection result to the memory controller.

In some implementations, the memory controller is further configured to: in response to the first memory cell block failing the erase page check, determine whether a number of first word lines coupled to programmed memory cell pages in the first memory cell block is greater than a third threshold; and in response to the number of the first word lines being not greater than the third threshold, send a second write command to the memory, the second write command instructing to write data into an unprogrammed memory cell page coupled to a second word line in the first memory cell block, the second word line being not adjacent to the first word lines; and the memory is further configured to: in response to the second write command, write the data into the unprogrammed memory cell page coupled to the second word line in the first memory cell block.

In some implementations, the memory controller is further configured to: in response to the number of the first word lines being greater than the third threshold, determine a second memory cell block into which the data is to be written, and send a third write command to the memory, the third write command instructing to write invalid data into the unprogrammed memory cell page in the first memory cell block; and the memory is further configured to: in response to the third write command, write the invalid data into the unprogrammed memory cell page in the first memory cell block.

In some implementations, the second write command further instructs to write invalid data into an unprogrammed memory cell page located between the programmed memory cell pages and the unprogrammed memory cell page coupled to the second word line; and the memory is further configured to: in response to the second write command, write the invalid data into the unprogrammed memory cell page located between the programmed memory cell pages and the unprogrammed memory cell page coupled to the second word line.

In a fourth aspect, it is provided a computer-readable storage medium having stored therein computer-executable instructions that, when executed, implement any method in the above-mentioned first aspect.

In a fifth aspect, it is provided a computer device, comprising a processor, and a readable storage medium coupled to the processor, the readable storage medium having stored therein computer-executable instructions that, when executed by the processor, implement any method in the above-mentioned first aspect.

It can be understood that the technical effects of the second aspect to the fifth aspect can refer to the technical effects of the first aspect and any implementation thereof and will not be repeated as disclosed here.

Implementations of the present application provide an operation method of a memory controller, a memory controller and a memory system. When a target parameter of an open block is not greater than a preset first threshold, that is, when unprogrammed memory cell pages are less affected, an erase page check is omitted and data is written into a first memory cell block. The time to perform the erase page check is saved, and the time to program the open block is reduced, thereby reducing programming time of the memory.

Those skilled in the art can clearly understand that the descriptions of each of the above-mentioned implementations has its own focus for the convenience and brevity of description, and the parts that are not described in detail in a certain implementation can be referred to the corresponding process in the aforementioned method implementation and will not be repeated as disclosed here.

It should be understood that in the various implementations of the present application, the magnitude of the sequence numbers of the above-mentioned processes does not mean the order of execution. The execution order of each process should be determined by its functions and internal logic, and should not constitutes any limitation to implementation process of the present application.

Those skilled in the art can appreciate that the modules and algorithm operations of the examples described in conjunction with the examples disclosed as disclosed here can be implemented in electronic hardware, or a combination of computer software and electronic hardware. Whether these functions are implemented in hardware or software depends on the specific application and design constraints of the technical solution. Skilled artisans may use different methods to implement the described functions for each specific application, but such example should not be regarded as going beyond the scope of the present application.

The above description is only a specific example of the present disclosure, but the scope of protection of the present disclosure is not limited thereto. Any changes or substitutions that can be easily conceived by those skilled in the art within the technical scope disclosed in the present disclosure shall be encompassed within the protection scope of the present disclosure. Therefore, the protection scope of the present disclosure should be determined by the protection scope of the claims.

What is claimed is:

1. An operation method of a memory controller, comprising:
in response to a data write instruction, determining a first memory cell block into which data is to be written;
determining whether a target parameter of the first memory cell block is greater than a first threshold; and
in response to the target parameter of the first memory cell block being not greater than the first threshold, writing the data into the first memory cell block.

2. The operation method of claim 1, further comprising:
in response to the target parameter of the first memory cell block being greater than the first threshold, performing an erase page check on the first memory cell block; and
in response to the first memory cell block passing the erase page check, writing the data into the first memory cell block.

3. The operation method of claim 2, wherein:
the target parameter of the first memory cell block comprises a read count of the first memory cell block; or
the target parameter of the first memory cell block comprises a placement duration of the first memory cell block, and the placement duration of the first memory cell block is a time difference between a current moment and a moment at which an erase operation was last performed on the first memory cell block.

4. The operation method of claim 3, further comprising:
determining the first threshold based on an erase count of the first memory cell block.

5. The operation method of claim 4, wherein the determining the first threshold based on a erase count of the first memory cell block comprises:
determining whether the erase count of the first memory cell block is greater than a second threshold;
in response to the erase count of the first memory cell block being greater than the second threshold, determining the first threshold to be a threshold a; and
in response to the erase count of the first memory cell block being not greater than the second threshold, determining the first threshold to be a threshold b,
wherein the threshold a is smaller than the threshold b.

6. The operation method of claim 2, further comprising:
in response to the first memory cell block failing the erase page check, determining whether a number of first word lines coupled to programmed memory cell pages in the first memory cell block is greater than a third threshold;
in response to the number of the first word lines being not greater than the third threshold, writing data into an unprogrammed memory cell page coupled to a second word line in the first memory cell block, the second word line being not adjacent to the first word lines; and
in response to the number of the first word lines being greater than the third threshold, determining a second memory cell block into which the data is to be written.

7. The operation method of claim 6, further comprising:
in response to the number of the first word lines being not greater than the third threshold, writing invalid data into an unprogrammed memory cell page located between the programmed memory cell pages and the unprogrammed memory cell page coupled to the second word line; and
in response to the number of the first word lines being greater than the third threshold, writing invalid data into the unprogrammed memory cell page in the first memory cell block.

8. A memory controller, comprising:
a buffer configured to store a target parameter of a first memory cell block; and
a processor configured to:
in response to a data write instruction, determine the first memory cell block into which data is to be written;
determine whether the target parameter of the first memory cell block is greater than a first threshold; and
in response to the target parameter of the first memory cell block being not greater than the first threshold, write the data into the first memory cell block.

9. The memory controller of claim 8, wherein the processor is further configured to:
in response to the target parameter of the first memory cell block being greater than the first threshold, perform an erase page check on the first memory cell block; and
in response to the first memory cell block passing the erase page check, write the data into the first memory cell block.

10. The memory controller of claim 9, wherein:
the target parameter of the first memory cell block comprises a read count of the first memory cell block; or
the target parameter of the first memory cell block comprises a placement duration of the first memory cell block, and the placement duration of the first memory cell block is a time difference between a current moment and a moment at which an erase operation was last performed on the first memory cell block, and
the buffer is configured to perform at least one of:
store the read count of the first memory cell block; or
store the placement duration of the first memory cell block.

11. The memory controller of claim 10, wherein the processor is further configured to:
determine the first threshold based on an erase count of the first memory cell block.

12. The memory controller of claim 11, wherein the processor determines the first threshold based on an erase count of the first memory cell block, and is configured to:
determine whether the erase count of the first memory cell block is greater than a second threshold;
in response to the erase count of the first memory cell block being greater than the second threshold, determine the first threshold to be a threshold a; and
in response to the erase count of the first memory cell block being not greater than the second threshold, determine the first threshold to be a threshold b,
wherein the threshold a is smaller than the threshold b.

13. The memory controller of claim 9, wherein the processor is further configured to:
in response to the first memory cell block failing the erase page check, determine whether a number of first word lines coupled to programmed memory cell pages in the first memory cell block is greater than a third threshold;
in response to the number of the first word lines being not greater than the third threshold, write data into an unprogrammed memory cell page coupled to a second word line in the first memory cell block, the second word line being not adjacent to the first word lines; and
in response to the number of the first word lines being greater than the third threshold, determine a second memory cell block into which the data is to be written.

14. The memory controller of claim 13, wherein the processor is further configured to:
in response to the number of the first word lines being not greater than the third threshold, write invalid data into an unprogrammed memory cell page located between the programmed memory cell pages and the unprogrammed memory cell page coupled to the second word line.

15. The memory controller of claim 13, wherein the processor is further configured to:
in response to the number of the first word lines being greater than the third threshold, write invalid data into the unprogrammed memory cell page in the first memory cell block.

16. A memory system, comprising:
a memory controller coupled to a memory and is configured to:
in response to a data write instruction, determine a first memory cell block into which data is to be written;
determine whether a target parameter of the first memory cell block is greater than a first threshold; and
in response to the target parameter of the first memory cell block being not greater than the first threshold, send a first write command to the memory, the first write command instructing the memory to write the data into the first memory cell block; and
the memory configured to:
in response to the first write command, write the data into the first memory cell block.

17. The memory system of claim 16, wherein,
the memory controller is further configured to:
in response to the target parameter of the first memory cell block being greater than the first threshold, send a detection command to the memory, the detection command instructing the memory to perform an erase page check on the first memory cell block;
receive a detection result sent by the memory and determine whether the first memory cell block passes the erase page check; and
in response to the first memory cell block passing the erase page check, send the first write command to the memory; and
the memory is further configured to:
in response to the detection command, perform the erase page check on the first memory cell block, and send the detection result to the memory controller.

18. The memory system of claim 17, wherein,
the memory controller is further configured to:
in response to the first memory cell block failing the erase page check, determine whether a number of first word lines coupled to programmed memory cell pages in the first memory cell block is greater than a third threshold; and
in response to the number of the first word lines being not greater than the third threshold, send a second write command to the memory, the second write command instructing to write data into an unprogrammed memory cell page coupled to a second word line in the first memory cell block, the second word line being not adjacent to the first word lines; and
the memory is further configured to:
in response to the second write command, write the data into the unprogrammed memory cell page coupled to the second word line in the first memory cell block.

19. The memory system of claim 18, wherein,
the memory controller is further configured to:
in response to the number of the first word lines being greater than the third threshold, determine a second memory cell block into which the data is to be written, and send a third write command to the memory, the third write command instructing to write invalid data into the unprogrammed memory cell page in the first memory cell block; and
the memory is further configured to:
in response to the third write command, write the invalid data into the unprogrammed memory cell page in the first memory cell block.

20. The memory system of claim 18, wherein the second write command further instructs to write invalid data into an unprogrammed memory cell page located between the programmed memory cell pages and the unprogrammed memory cell page coupled to the second word line; and the memory is further configured to:
in response to the second write command, write the invalid data into the unprogrammed memory cell page located between the programmed memory cell pages and the unprogrammed memory cell page coupled to the second word line.
